(19) United States
(12) Patent Application Publication
(10) Pub. No.: US 2013/0162280 A1
(43) Pub. Date: Jun. 27, 2013

(54) PROBE CARD AND METHOD OF MANUFACTURING THE SAME

(71) Applicants: Doo Yun CHUNG, Seoul (KR); Dae Hyeong LEE, Seoul (KR); Ki Pyo HONG, Suwon (KR); Won Chul MA, Suwon (KR); Yong Seok CHOI, Suwon (KR)

(72) Inventors: Doo Yun CHUNG, Seoul (KR); Dae Hyeong LEE, Seoul (KR); Ki Pyo HONG, Suwon (KR); Won Chul MA, Suwon (KR); Yong Seok CHOI, Suwon (KR)

(73) Assignee: Samsung Electro-Mechanics Co., Ltd.

(21) Appl. No.: 13/532,435

(22) Filed: Jun. 25, 2012

(30) Foreign Application Priority Data
Dec. 22, 2011 (KR) 10-2011-0140022

(51) Int. Cl. G01R 31/26; B23K 31/02

(52) U.S. Cl. 324/756.03; 228/165

(57) ABSTRACT

There are provided a probe card and a method of manufacturing the same, in which an electrode pad having a probe pin bonded thereto may be prevented from being delaminated from a substrate. The probe card according to embodiments of the present invention may include a ceramic substrate including at least one pad groove formed in one surface thereof and an electrode pad embedded in the pad groove; and a probe pin bonded to the electrode pad.

### CROSS-REFERENCE TO RELATED APPLICATIONS

This application claims the priority of Korean Patent Application No. 10-2011-0140022 filed on Dec. 22, 2011, in the Korean Intellectual Property Office, the disclosure of which is incorporated herein by reference.

### BACKGROUND OF THE INVENTION

1. Field of the Invention

The present invention relates to a probe card and a method of manufacturing the same.

2. Description of the Related Art

Due to recent development of integration technology for semiconductor circuits, miniaturization of semiconductor devices has been continuously conducted, and accordingly, apparatuses for testing semiconductor chips are also required to have high precision.

Integrated circuit chips formed on a semiconductor wafer through a wafer fabrication process are classified into good products and defective products through electrical die sorting (EDS) conducted in a wafer state thereof.

In general, a test apparatus including a tester for generating test signals and determining test results, a probe station for loading or unloading a semiconductor wafer, and a probe card for electrically connecting the semiconductor wafer and the tester, is mainly used in the electric die sorting.

Among them, the probe card mainly employs a structure in which a probe pin is bonded to a ceramic substrate fabricated by forming and laminating circuit patterns, electrode pads, via electrodes, and the like on a ceramic green sheet and then firing the laminate.

A probe card according to the related art has a structure in which a probe pin is bond to a metal layer of a substrate. This metal layer is formed through plating or the like, and thus, a height difference in the metal layer may occur during a plating process in accordance with an increase in the size of the substrate.

When a plurality of probe pins are soldered on the metal layer having the height difference, without separate post-processing, respective probe pins may have different heights after soldering due to the height difference in the metal layer. Therefore, a metal layer planarization process needs to be previously performed before soldering, in order to remove the differences in height of the probe pins.

Meanwhile, in the case in which some of the probe pins are replaced due to defects thereof, not only the corresponding probe pins but also electrode pads attached to the corresponding probe pin may be simultaneously detached from the substrate at the time of separating the corresponding probe pin from the substrate.

This delamination phenomenon of the electrode pad may also occur when the probe pin is re-bonded to the substrate.

### SUMMARY OF THE INVENTION

An aspect of the present invention provides a probe card, and a method of manufacturing the same, in which a manufacturing time is shortened and manufacturing costs are reduced by not performing a metal layer planarization process and only a part of probe pins is easily replaced at the time of defects occurrence.

According to an aspect of the present invention, there is provided a probe card, including: a substrate; one or more metal layers formed on one surface of the substrate to be spaced apart from each other, each metal layer having a groove part; one or more probe pins each inserted into the groove part of each metal layer; and a soldering layer formed on one surface of the metal layer and in the groove part and allowing each probe pin to be bonded to the groove part.

The metal layers may be formed of one or an alloy of at least two selected from a group consisting of silver (Ag), gold (Au), palladium (Pd), platinum (Pt), rhodium (Rh), copper (Cu), titanium (Ti), tungsten (W), molybdenum (Mo) and nickel (Ni).

The soldering layer may be formed of at least one of tin (Sn), gold-tin (Au—Sn) and silver-tin (Ag—Sn).

Each of the probe pins may include: a contact part; a body part connected to one end of the contact part and supporting the contact part; and a bonding part connected to one end of the body part and having at least a portion bonded to the groove part through the soldering layer while being inserted into the groove part.

The probe pins may be formed of one or a combination of two or more selected from a group consisting of titanium (Ti), nickel (Ni), cobalt (Co), tungsten (W), nickel-cobalt (NiCo), nickel-cobalt-tungsten (NiCoW), platinum (Pt), and rhodium (Rh).

According to another aspect of the present invention, there is provided a method of manufacturing a probe card, the method including: preparing a substrate; forming a seed layer on one surface of the substrate; forming a photosensitive film on the seed layer; forming a plurality of holes spaced apart from each other by exposing and developing the photosensitive film; forming a metal layer in each of the holes; forming a soldering layer on the metal layer; exposing a part of one surface of the substrate by forming a plurality of groove parts penetrating the metal layer and the soldering layer; allowing a probe pin to contact the exposed part of the substrate by inserting the probe pin into each of the groove parts; and bonding the probe pin to each groove part by melting the soldering layer to forma solder on a surface of the metal layer and in the groove part.

In the forming of the holes, plasma ashing may be performed on a part of the photosensitive film.

The forming of the metal layer may be performed by plating one or an alloy of at least two selected from a group consisting of silver (Ag), gold (Au), palladium (Pd), platinum (Pt), rhodium (Rh), copper (Cu), titanium (Ti), tungsten (W), molybdenum (Mo) and nickel (Ni), in the holes formed in the substrate.

The forming of the soldering layer may be performed by plating at least one of gold (Au) and tin (Sn) on the metal layer.

In the bonding of the probe pin, the melted soldering layer may be introduced through the groove part so as to fill a gap between an inner wall of the groove part and the probe pin.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a partial process cross-sectional view explaining a method of manufacturing a probe card according to an embodiment of the present invention;

FIG. 2 is an exploded perspective view schematically showing a coupling structure of a substrate and probe pins in the probe card according to the embodiment of the present invention;

FIG. 3 is a perspective view schematically showing the probe card according to the embodiment of the present invention;

FIG. 4 is a cross sectional view showing a structure before soldering of the probe pins in the probe card of FIG. 3;

FIG. 5 is a cross sectional view showing a structure after soldering of the probe pins in the probe card of FIG. 3; and

FIG. 6 is a process flow showing a method of manufacturing the probe card according to the embodiment of the present invention.

### DETAILED DESCRIPTION OF THE PREFERRED EMBODIMENT

Hereinafter, embodiments of the present invention will be described in detail with reference to the accompanying drawings.

However, the invention may be embodied in many different forms and should not be construed as being limited to the embodiments set forth herein.

The embodiments of the present invention are provided so that those skilled in the art may more completely understand the present invention.

In the drawings, the shapes and dimensions may be exaggerated for clarity, and the same reference numerals will be used throughout to designate the same or like components.

In addition, like reference numerals denote parts performing similar functions and actions throughout the drawings.

In addition, unless explicitly described otherwise, “comprising” any components will be understood to imply the inclusion of other components but not the exclusion of any other components.

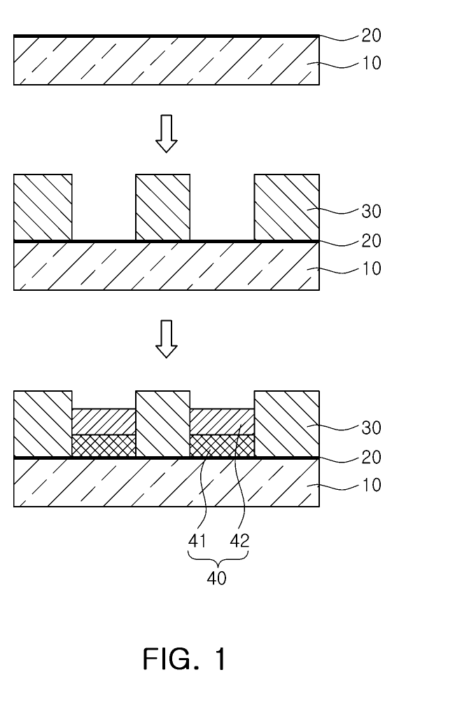

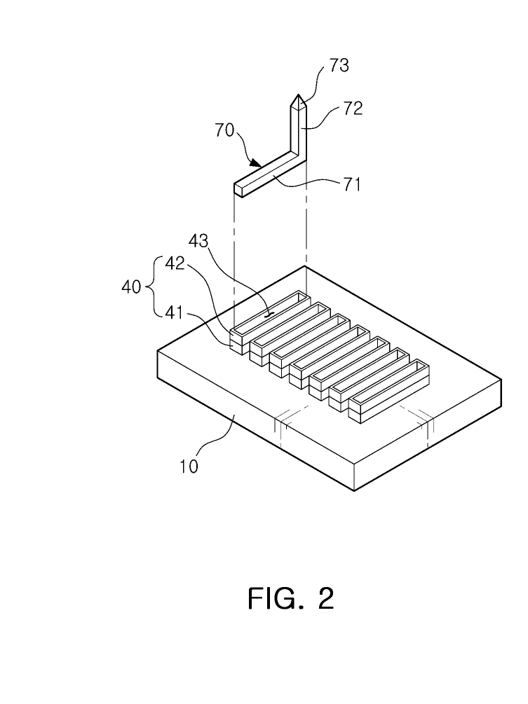

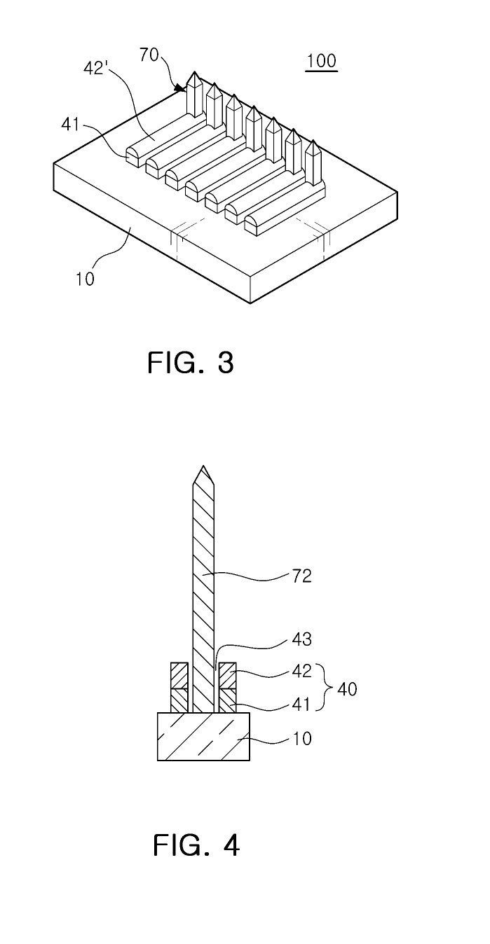

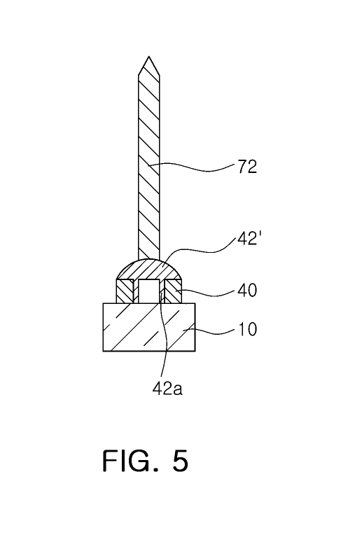

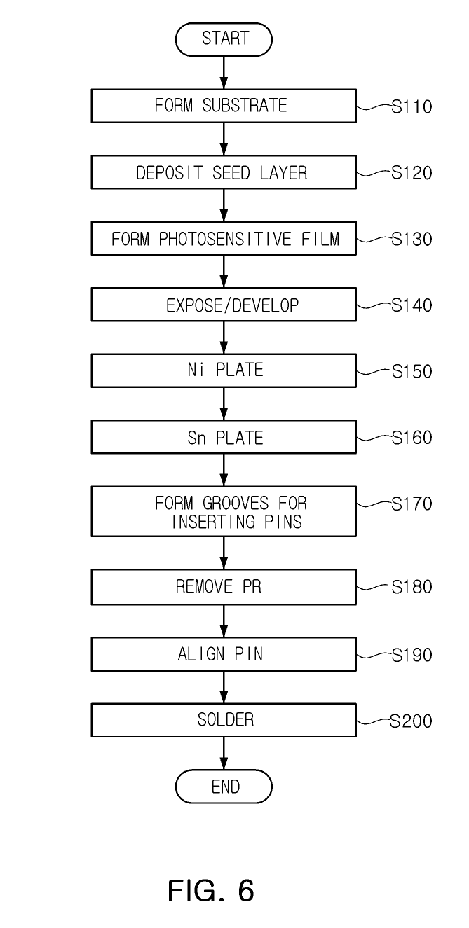

FIG. 1 is a partial process cross-sectional view explaining a method of manufacturing a probe card according to an embodiment of the present invention. FIG. 2 is an exploded perspective view schematically showing a coupling structure of a substrate and probe pins in the probe card according to the embodiment of the present invention. FIG. 3 is a perspective view schematically showing the probe card according to the embodiment of the present invention. FIG. 4 is a cross sectional view showing a structure before soldering of the probe pins in the probe card of FIG. 3. FIG. 5 is a cross sectional view showing a structure after soldering of the probe pins in the probe card of FIG. 3.

Referring to FIGS. 1 to 5, a probe card 100 according to the embodiment may include a substrate 10, and a plurality of probe pins 70 bonded to one surface of the substrate 10 and physically and electrically connected to the substrate 10.

Here, bonding parts 40 may be formed on one surface of the substrate 10. Each of the bonding parts 40 may include a metal layer 41 disposed at a lower portion thereof and a soldering layer 42 formed on the metal layer 42. Each bonding part 40 may have a groove part 43 formed therein so that one end of each probe pin 70 may penetrate the metal layer 41 and the soldering layer 42 to be inserted into the groove part 43.

Here, in the embodiment, the soldering layer 42 is shown to have a hemispherical shape, but the present invention is not limited thereto. A cross-section of the soldering layer 42 may be variously changed, such as having a square shape, a triangle shape, or the like, as long as the end of each probe pin 70 may be completely surrounded.

In the embodiment, for the convenience of explanation, a probe substrate and a ceramic substrate will be used and described as the substrate, but the two substrates refer to as the same component.

The substrate 10 may be fabricated by laminating a plurality of ceramic green sheets and performing firing thereon, the ceramic green sheets being formed as a plurality of ceramic layers.

Here, each ceramic layer may have wiring patterns (not shown) and conductive vias (not shown) vertically connecting the wiring patterns.

In addition, a circuit pattern (not shown) maybe formed on one surface of the substrate 10. The metal layer 41 of each bonding part 40 may be physically and electrically connected to the via electrodes (not shown) connected to an inside of the substrate 10 by the circuit pattern to thereby serve as an electrode pad.

Meanwhile, the substrate 10 according to the embodiment of the present invention may be formed as a low-temperature co-fired ceramic (LTCC) substrate, but the present invention is not limited thereto.

This is because that, when the substrate 10 is formed as a high-temperature co-fired ceramic (HTCC) substrate, firing thereof may be performed at about 1500 to 1700° C. and accordingly, tungsten (W), molybdenum (Mo), or the like needs to be used as a conductive material. However, in this case, process costs are increased and high dimensional precision for large-area precise patterns may not be obtained.

When the substrate 10 is an LTCC substrate as above, a ceramic laminate may be formed by preparing ceramic green sheets by using a doctor blade process or the like, forming conductive vias and inner electrodes on each of the ceramic green sheets in an appropriate manner, and laminating the ceramic green sheets.

Thereafter, the ceramic laminate may be fired at about 700 to 900° C. to obtain a ceramic sintered body.

The metal layer 41 maybe formed of a conductive material through which current flows. For example, the metal layer 41 may be formed of one or an alloy of at least two selected from the group consisting of silver (Ag), gold (Au), palladium (Pd), platinum (Pt), rhodium (Rh), copper (Cu), titanium (Ti), tungsten (W), molybdenum (Mo) and nickel (Ni), which may have superior durability and abrasion resistance. However, the present invention is not limited thereto.

The soldering layer 42 may be formed of at least one of tin (Sn), gold-tin (Au—Sn) and silver-tin (Ag—Sn). Here, a gold (Au) layer may be further formed on the probe pins 70 in order to improve solderability.

The probe pins 70 maybe formed of a conductive material through which current flows. For example, the probe pin 70 may be formed of one or a combination of at least two selected from the group consisting of titanium (Ti), nickel (Ni), cobalt (Co), nickel-cobalt (NiCo), nickel-cobalt-tungsten (NiCoW), tungsten (W), platinum (Pt), and rhodium (Rh), which may have superior durability and abrasion resistance.

The probe pins 70 may be fabricated by using a micro thin sheet technique used in manufacturing a semiconductor.

In addition, each of the probe pins 70 according to the embodiment may be configured to have a cantilever shape, but may be changed to various shapes. For example, the probe pin 70 may have a straight line shape to be bonded to the substrate 10 in a perpendicular manner.

Each probe pin 70 may include a bonding part 71, a body part 72, and a contact part 73.

The bonding part 71 may have a quadrangular plate shape so as to secure the maximum contact area with the substrate 10 and the groove part 43. The bonding part 71 may be inserted into the groove part 43 of the substrate 10 and electrically connected to the substrate 10.

The body part 72 may include one end connected to the bonding part 71 and the other end connected to the contact part 73.

Here, a surface of the body part 72 may be plated with a metal material having high conductivity, such as gold (Au), nickel (Ni), copper (Cu), or the like, in order to prevent distortion of the probe pin 70 and improve rigidity thereof.

The contact part 73 may include an end having a V-shape or a tip shape so as to contact with an object (not shown) to be inspected, such as a wafer die or the like.

In other words, the contact part 73 may contact with the object to transmit an electric signal received from a test apparatus to the object and re-transmit a signal received from the object to the probe card 100.

Hereinafter, a method of manufacturing the probe card 100 according to the embodiment of the present invention will be described.

As shown in FIG. 1, the substrate 10 may be prepared by laminating a plurality of ceramic layers having wiring patterns and via electrodes formed thereon and performing sintering thereto (S110).

Here, as described above, the substrate 10 may be a low-temperature co-fired ceramic (hereinafter, referred to as LTCC) substrate.

The LTCC substrate 10 may be formed by preparing ceramic green sheets through a doctor blade process or the like, forming wiring patterns and via electrodes on each of the ceramic green sheets, and then laminating and sintering the ceramic green sheets. Here, the sintering process may be performed at a temperature of about 700 to 900° C.

Next, a cleaning process is performed to remove foreign substances such as, oil stain, oxides or the like, from the substrate 10, and then a seed layer 20 is deposited thereon (S120).

The seed layer 20 may be formed to have double layers by sequentially depositing a titanium (Ti) layer and a gold (Au) layer. Here, the titanium (Ti) layer may function as a wetting layer so that a conductive layer is satisfactorily deposited on the substrate 10. The gold layer (Au) may function as the conductive layer, but the present invention is not limited thereto.

Next, a photosensitive film 30 having a predetermined thickness is formed on the seed layer 20 (S130).

Then, a part of the photosensitive film 30 may be exposed and developed to form a plurality of holes therein, the plurality of holes being spaced apart from each other, such that an upper surface of the seed layer 20 may be exposed to the outside (S140).

Here, in order to remove an unnecessary portion of the photosensitive film 30, a method such as plasma ashing using oxygen plasma or the like may be used, but the present invention is not limited thereto.

Next, the metal layer 41 may be formed in each of the holes by using an electroplating method or the like (S150).

However, a method of forming the metal layer 41 is not limited thereto, and various methods such as electroless plating, screen printing, sputtering, and the like may be employed, if necessary.

In other words, first, after a base layer having conductivity may be formed on the substrate 10 and the substrate 10 may be impregnated with an electrolytic liquid, the metal layer 41 may be grown through voltage application to the base layer.

The metal layer 41 may be formed of a conductive material. In particular, the metal layer 41 may be preferably formed of a material that may be easily bonded to a material for forming the circuit pattern formed on the substrate 10 or the probe pin 70 and have bonding strength therewith.

As the conductive material, one or an alloy of at least two selected from the group consisting of silver (Ag), gold (Au), palladium (Pd), platinum (Pt), rhodium (Rh), copper (Cu), titanium (Ti), tungsten (W), molybdenum (Mo) and nickel (Ni) may be used, so that durability of the probe card can be improved, and thus, performance of the probe card can be uniformly maintained despite of a long term use.

Next, the soldering layer 42 may be formed on the metal layer 41 by electroplating to form each bonding part 40 (S160).

However, a method of forming the soldering layer 42 is not limited thereto, and various methods such as, if necessary, electroless plating, screen printing, sputtering, and the like may be used.

Here, gold (Au), tin (Sn), or the like mainly used in soldering may be employed as a material of the soldering layer 42, but the present invention is not limited thereto.

Next, the groove part 43 may be formed in the bonding part 40 such that the groove part 43 penetrates the metal layer 41 and the soldering layer 20 in a perpendicular manner, whereby a part of an upper surface of the substrate 10 may be exposed (S170). The photosensitive film 30 remaining on the upper surface of the substrate 10 may be completely removed (S180).

Here, a method of forming the groove part 43 is simply performed by removing photoresist, the photosensitive film 30, but the present invention is not limited thereto.

Next, the bonding part 71 of each probe pin 70 may be inserted into the groove part 43 of the bonding part 40 so that the probe pin 70 directly contacts the exposed surface of the substrate 10 and electrically connected to the substrate 10 (S190).

Here, a circuit pattern may be formed on the surface of the substrate 10 such that the via electrodes of the substrate 10 may be electrically connected to the metal layer 41.

Next, soldering is performed by using the soldering layer 42 (S200).

In other words, the probe pin 70 and the substrate 10 may be bonded to each other by using a solder (42′) produced by melting the soldering layer 42.

Here, a part (42a) of the solder maybe introduced into the groove part 43 of the bonding part 40 to fill a gap between an inner wall of the groove part 43 and the bonding part 71, to thereby allow for an extended bonding area between the probe pin 70 and the bonding part 40. Thus, bonding strength between the probe pin 70 and the substrate 10 may be further improved.

Meanwhile, a probe card according to the related art has a structure in which a probe pin is bond to a metal layer of a substrate. This metal layer is formed through plating or the like, and thus, a height difference in the metal layer may occur during a plating process in accordance with an increase in the size of the substrate.

When a plurality of probe pins are soldered on the metal layer having the height difference, without separate post-processing, respective probe pins may have different heights after soldering due to the height difference in the metal layer. Therefore, a metal layer planarization process needs to be previously performed before soldering, in order to remove the differences in height of the probe pins.

However, in the embodiment of the present invention, since the bonding part 71 of each probe pin 70 directly contacts a surface of the substrate 10, such that the probe pins 70 may hardly have height differences without performing the metal layer planarization process. Thus, the number of processing processes may be decreased to shorten a manufacturing time and reduce manufacturing costs.

In addition, in a case in which some of the probe pins 70 are replaced due to defects, the corresponding probe pins 70 are separated from the substrate 10 by irradiating laser to the solder 42′ and 42a.

Here, since the bonding part 71 of each probe pin 70 directly contacts the upper surface of the substrate 10, rather than the metal layer 41, delamination of the metal layer 41 may be prevented at the time of separation or re-bonding of the probe pins 70.

Therefore, when the probe card is defective, repairing operation may be easily undertaken.

According to embodiments of the present invention, a manufacturing time can be shortened and manufacturing costs can be reduced by not performing a metal layer planarization process. Further, in the case in which some of probe pins are removed from or re-bonded to a substrate, it is possible to prevent electrode pads attached to the probe pins from being delaminated from the substrate. Therefore, when the probe card is defective, a repairing operation can be easily undertaken.

The present invention is not limited to the above-described embodiments and the accompanying drawings, but defined by the accompanying claims.

Accordingly, various forms of substitutions, modifications and alterations may be made by those skilled in the art without departing from the spirit of the prevent invention defined by the accompanying claims. These substitutions, modifications and alterations are considered as being within the scope of the present invention.

What is claimed is:

1. A probe card, comprising:
a substrate;
one or more metal layers formed on one surface of the substrate to be spaced apart from each other, each metal layer having a groove part;
one or more probe pins each inserted into the groove part of each metal layer; and
a soldering layer formed on one surface of the metal layer and in the groove part and allowing each probe pin to be bonded to the groove part.

2. The probe card of claim 1, wherein the metal layers are formed of one or an alloy of at least two selected from a group consisting of silver (Ag), gold (Au), palladium (Pd), platinum (Pt), rhodium (Rh), copper (Cu), titanium (Ti), tungsten (W), molybdenum (Mo) and nickel (Ni).

3. The probe card of claim 1, wherein the soldering layer is formed of at least one of tin (Sn), gold-tin (Au—Sn) and silver-tin (Ag—Sn).

4. The probe card of claim 1, wherein each of the probe pins includes:
a contact part;
a body part connected to one end of the contact part and supporting the contact part; and
a bonding part connected to one end of the body part and having at least a portion bonded to the groove part through the soldering layer while being inserted into the groove part.

5. The probe card of claim 1, wherein the probe pins are formed of one or a combination of two or more selected from a group consisting of titanium (Ti), nickel (Ni), cobalt (Co), tungsten (W), nickel-cobalt (NiCo), nickel-cobalt-tungsten (NiCoW), platinum (Pt), and rhodium (Rh).

6. A method of manufacturing a probe card, the method comprising:
preparing a substrate;
forming a seed layer on one surface of the substrate;
forming a photosensitive film on the seed layer;
forming a plurality of holes spaced apart from each other by exposing and developing the photosensitive film;
forming a metal layer in each of the holes;
forming a soldering layer on the metal layer;
exposing a part of one surface of the substrate by forming a plurality of groove parts penetrating the metal layer and the soldering layer;
allowing a probe pin to contact the exposed part of the substrate by inserting the probe pin into each of the groove parts; and
bonding the probe pin to each groove part by melting the soldering layer to forma solder on a surface of the metal layer and in the groove part.

7. The method of claim 6, wherein in the forming of the holes, plasma ashing is performed on a part of the photosensitive film.

8. The method of claim 6, wherein the forming of the metal layer is performed by plating one or an alloy of at least two selected from a group consisting of silver (Ag), gold (Au), palladium (Pd), platinum (Pt), rhodium (Rh), copper (Cu), titanium (Ti), tungsten (W), molybdenum (Mo) and nickel (Ni), in the holes formed in the substrate.

9. The method of claim 6, wherein the forming of the soldering layer is performed by plating at least one of gold (Au) and tin (Sn) on the metal layer.

10. The method of claim 6, wherein in the bonding of the probe pin, the melted soldering layer is introduced through the groove part so as to fill a gap between an inner wall of the groove part and the probe pin.
